(19) United States
(12) Patent Application Publication
(10) Pub. No.: US 2026/0171352 A1
(43) Pub. Date: Jun. 18, 2026

(54) CHARGED PARTICLE BEAM WRITING APPARATUS

(71) Applicant: NuFlare Technology, Inc., Yokohama-shi (JP)

(72) Inventor: Yoshiyuki NEGISHI, Koshigaya-shi (JP)

(73) Assignee: NuFlare Technology, Inc., Yokohama-shi (JP)

(21) Appl. No.: 19/363,779

(22) Filed: Oct. 21, 2025

(30) Foreign Application Priority Data
Dec. 17, 2024 (JP) 2024-220949

(51) Int. Cl. H01J 37/30; H01J 37/317

(52) U.S. Cl. CPC H01J 37/3007; H01J 37/3177; H01J 2237/043; H01J 2237/0455

(57) ABSTRACT

In one embodiment, a charged particle beam writing apparatus includes a charged particle source generating and emitting a beam, a blanker controlling ON/OFF of the beam, a stopping aperture substrate having a first opening through which the beam, when controlled to be ON by the blanker, passes toward a substrate, a scattering section through which the beam transmits while being scattered when deflected by the blanker to be OFF, and an absorbing member that absorbs the beam having transmitted through the scattering section.

### CROSS REFERENCE TO RELATED APPLICATION

This application is based upon and claims benefit of priority from the Japanese Patent Application No. 2024-220949, filed on December 17, 2024, the entire contents of which are incorporated herein by reference.

### FIELD

The present invention relates to a charged particle beam writing apparatus.

### BACKGROUND

As LSI circuits are increasing in density, the required linewidths of circuits included in semiconductor devices become finer year by year. To form a desired circuit pattern on a semiconductor device, a method is employed in which a high-precision original pattern formed on quartz is transferred to a wafer in a reduced manner by using a reduced-projection exposure apparatus. High-precision original patterns are written by an electron beam writing apparatus, and so-called electron beam lithography technique is used.

Some writing apparatuses use a multi-beam, for example. As compared to when writing is performed with a single electron beam, use of a multi-beam allows many beams to be emitted at a time, thus the throughput can be significantly improved. In a multi-beam writing apparatus, for example, an electron beam emitted from an electron source is passed through a shaping aperture array substrate having multiple openings to form a multi-beam, and each beam is individually blanking-deflected by a blanking aperture array substrate to perform on/off control. The beam blanking-deflected by the blanking aperture array substrate is blocked by a stopping aperture substrate, and the beam not deflected is passed through an opening of the stopping aperture substrate, and a desired position on a sample is irradiated with the beam.

The writing apparatus is provided with a collective blanking deflector (common blanker) that collectively performs blanking deflection on the entire multi-beam to perform ON/OFF control. The multi-beam deflected by the collective blanking deflector is blocked by the stopping aperture substrate.

When blocking the beam on which blanking deflection has been performed, the stopping aperture substrate is charged, or the temperature thereof increases. The charge of the stopping aperture substrate affects the trajectory of the beam to shift the beam irradiation position on a sample, and the temperature increase causes the opening position to vary by bending of the substrate due to thermal expansion, thus a problem arises in that the writing accuracy may be reduced.

### BRIEF DESCRIPTION OF THE DRAWINGS

FIG. 1 is a schematic configuration view of a writing apparatus according to an embodiment of the present invention.

FIG. 2 is a plan view of a shaping aperture array substrate.

FIG. 3 is a schematic configuration view of a stopping aperture substrate and an electron absorbing member.

FIG. 4 is a schematic configuration view of a stopping aperture substrate and an electron absorbing member.

FIG. 5 is a schematic configuration view of an electron absorbing member according to a variation.

FIG. 6 is a schematic configuration view of a stopping aperture substrate and a scattering thin film.

FIG. 7 is a schematic configuration view of a stopping aperture substrate and a scattering thin film.

### DETAILED DESCRIPTION

In one embodiment, a charged particle beam writing apparatus includes a charged particle source generating and emitting a beam, a blanker controlling ON/OFF of the beam, a stopping aperture substrate having a first opening through which the beam, when controlled to be ON by the blanker, passes toward a substrate, a scattering section through which the beam transmits while being scattered when deflected by the blanker to be OFF, and an absorbing member that absorbs the beam having transmitted through the scattering section.

In the following embodiments, a configuration using an electron beam will be described as an example of a charged particle beam. However, the charged particle beam is not limited to the electron beam, and may be a beam using charged particles such as an ion beam.

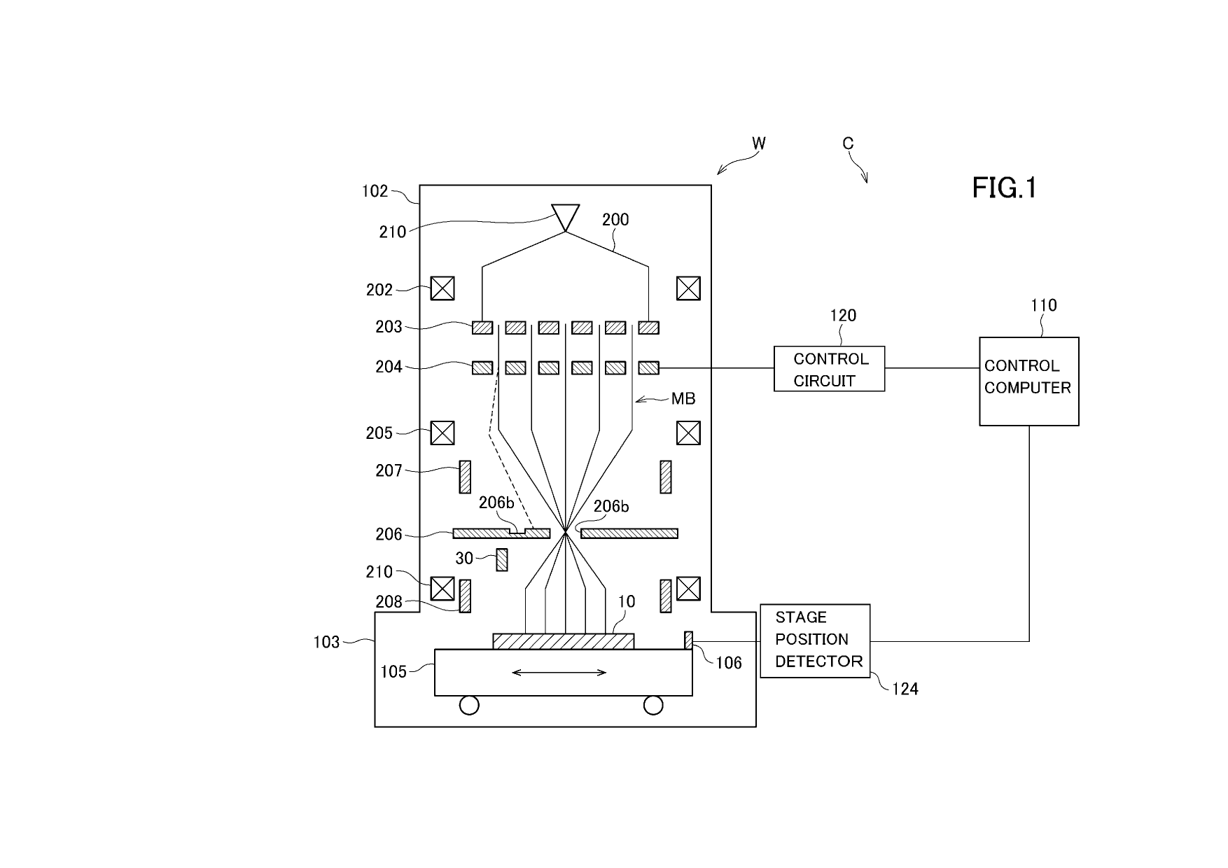

FIG. 1 is a schematic configuration view of a multi-beam writing apparatus according to an embodiment of the present invention. As illustrated in FIG. 1, the multi-beam writing apparatus includes a writer W and a controller C. The writer W includes an electron optical column 102 and a writing chamber 103. In the electron optical column 102, an electron source 201, an illumination lens 202, a shaping aperture array substrate 203, a blanking aperture array substrate 204, a reduction lens 205, a stopping aperture substrate 206, a collective blanking deflector 207, an electron absorbing member 30, a deflector 208, and an objective lens 210 are disposed, which constitute an electron optical system of the multi-beam writing apparatus.

An XY stage 105 movable in the XY direction is disposed in the writing chamber 103. The XY stage 105 may be movable in the Z direction. A substrate 10 as a writing target is disposed on the XY stage 105. The substrate 10 includes, for example, an exposure mask when a semiconductor device is manufactured, and a semiconductor substrate (silicon wafer) on which a semiconductor device is manufactured. In addition, the substrate 10 includes a mask blank coated with resist, on which no pattern has yet been written.

In addition, a mirror 106 for stage position measurement is disposed on the XY stage 105.

The controller C includes a control computer 110, a control circuit 120 and a stage position detector 124. The stage position detector 124 emits a laser, receives reflected light from the mirror 106, and detects the position of the XY stage 105 based on the principle of laser interferometry.

FIG. 1 illustrates the components necessary for explaining the embodiment, and other components are not illustrated.

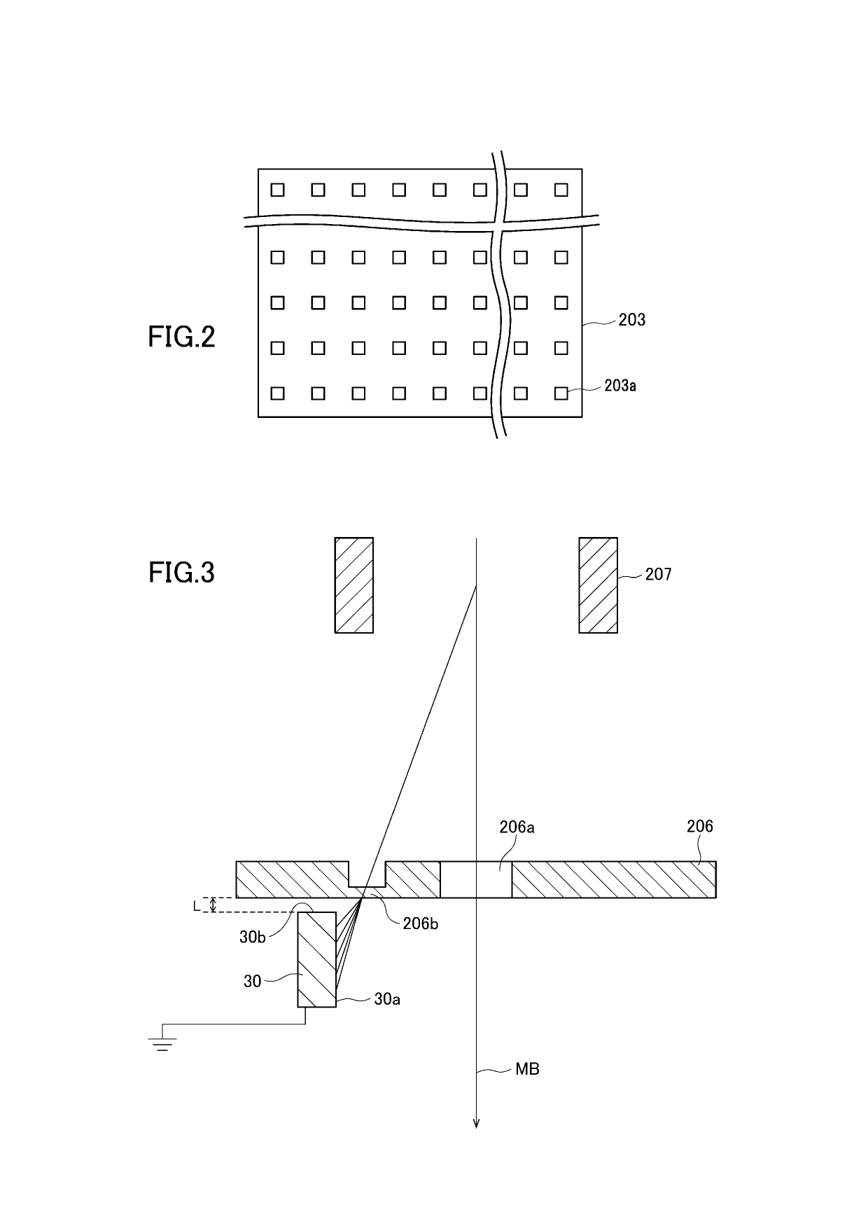

FIG. 2 is a conceptual view illustrating the configuration of the shaping aperture array substrate 203. In the shaping aperture array substrate 203 of FIG. 2, openings 203a in p columns in the vertical (y) direction and q rows in the horizontal (x) direction (p, q >=2) are formed in a matrix pattern at a predetermined arrangement pitch. For example, the openings 203a in 512 columns × 512 rows are formed. The openings 203a are formed in rectangular shapes having the same dimensions. The openings 203a may be circular. Part of an electron beam 200 emitted from the electron source 201 passes through a corresponding one of these multiple openings 203a, thereby forming a multi-beam MB.

The blanking aperture array substrate 204 is provided below the shaping aperture array substrate 203, and passage holes are formed corresponding to the arranged positions of the openings 203a of the shaping aperture array substrate 203. Each passage hole is provided with an individual blanker consisting of a set of two paired electrodes. One electrode of the individual blanker is fixed at the ground electric potential, and the other electrode is switched between the ground electric potential and another electric potential. Electron beams passing through respective passage holes are each independently deflected by a voltage applied to a corresponding individual blanker. Thus, multiple individual blankers perform blanking deflection on corresponding beams in the multi-beam MB which has passed through the multiple openings 203a of the shaping aperture array substrate 203.

The multi-beam MB which has passed through the blanking aperture array substrate 204 is reduced by the reduction lens 205, and travels to an opening 206a formed in the stopping aperture substrate 206.

The collective blanking deflector 207 collectively performs blanking deflection control on the multi-beam which has passed through the blanking aperture array substrate 204.

The beam (controlled to be ON) which has not been deflected by any individual blanker of the blanking aperture array substrate 204 and the collective blanking deflector 207 passes through the opening 206a of the stopping aperture substrate 206.

The multi-beam which has passed through the opening 206a of the stopping aperture substrate 206 is focused by the objective lens 210 to form a pattern image with a desired reduction ratio, and is collectively deflected by the deflector 208 and irradiated onto the substrate 10. For example, when the XY stage 105 is moved continuously, the irradiation position of the beam is controlled by the deflector 208 so that the irradiation position of the beam follows the movement of the XY stage 105.

The control computer 110 of the controller C reads writing data from a storage device (not illustrated), and performs a plurality of stages of data conversion to generate shot data. For example, the shot data defines whether or not irradiation is to be performed to each of multiple irradiation areas in a lattice pattern, and the irradiation time, the irradiation areas being obtained by dividing a writing surface of the substrate 10 by the beam size. The control computer 110 outputs a control signal to the control circuit 120 based on the shot data. The control circuit 120 controls the writer W based on the control signal. For example, the control circuit 120 controls ON/OFF of the beam by controlling the voltage applied to the individual blankers of the blanking aperture array substrate 204 and the electrodes of the collective blanking deflector 207. In addition, the control circuit 120 controls the deflection amount of the deflector 208, and controls the movement speed of the XY stage 105 based on the position of the XY stage 105.

The beam (controlled to be OFF) deflected (blanked) by an individual blanker of the blanking aperture array substrate 204 deviates from the position of the opening 206a of the stopping aperture substrate 206, and is blocked by the stopping aperture substrate 206.

The stopping aperture substrate 206 is a plate-like member having a thickness of approximately 300 to 500 μm, and made of tantalum or ruthenium. The stopping aperture substrate 206 is, for example, circular, and the opening 206a is formed in the center thereof.

As illustrated in FIG. 3, a recess is formed in a portion of the stopping aperture substrate 206, the portion being a scattering section 206b with which the beam controlled to be beam-OFF collides, and which has a small thickness. The thickness of the scattering section 206b is approximately 1 to 20 μm. When passing through the scattering section 206b, the multi-beam deflected by the collective blanking deflector 207 is scattered by the scattering section 206b.

The electron absorbing member 30 is provided below (downstream in the beam travel direction) the stopping aperture substrate 206. The material for the electron absorbing member 30 preferably is lower in density, and higher in electrical conductivity than the material for the stopping aperture substrate 206, and for example, titanium or aluminum may be used. The electron absorbing member 30 is connected to the ground.

The electron absorbing member 30 is disposed to absorb the beam (electron) which is scattered by the scattering section 206b. For example, the electron absorbing member 30 has a rectangular parallelepiped shape, and absorbs, by a lateral surface 30a, the beam scattered by the scattering section 206b. Here, the lateral surface 30a is a surface parallel to the beam travel direction (the travel direction of the beam on which no blanking deflection is performed).

The beam array size absorbed by the electron absorbing member 30 can be made larger than the beam array size on the stopping aperture substrate 206 by scattering the beam with the scattering section 206b. The area (electron receiving area) on which the beam is received can be increased by absorbing the beam by the lateral surface 30a of the electron absorbing member 30.

When an interval L between the stopping aperture substrate 206 and the electron absorbing member 30 is 2 mm, and a scattering angle of electrons caused by the scattering section 206b is 30°, the beam array size on the lateral surface 30a of the electron absorbing member 30 can be enlarged to about 200 times the beam array size on the stopping aperture substrate 206.

When the angle formed by the lateral surface 30a of the electron absorbing member 30, and the central beam in the multi-beam on which blanking deflection has been performed by the collective blanking deflector 207 is 5°, the electron receiving area on the lateral surface 30a can be expanded to approximately 10 times the electron receiving area on the stopping aperture substrate 206.

The electron absorbing member 30 is made of a material with high electrical conductivity, thus can absorb electrons efficiently. Absorbing the beam scattered by the lateral surface 30a inclined at an angle reduces a local temperature increase of the electron absorbing member 30.

In this manner, the beam controlled to be beam-OFF is scattered by the scattering section 206b, and absorbed by the electron absorbing member 30, thereby making it possible to reduce charging and temperature increase of the stopping aperture substrate 206 and to achieve highly accurate writing.

The beam scattered by the scattering section 206b may be absorbed by an upper surface 30b of the electron absorbing member 30. In this case, it is preferable that the electron absorbing member 30 be disposed so that the beam reflected by the upper surface 30b does not reach the stopping aperture substrate 206.

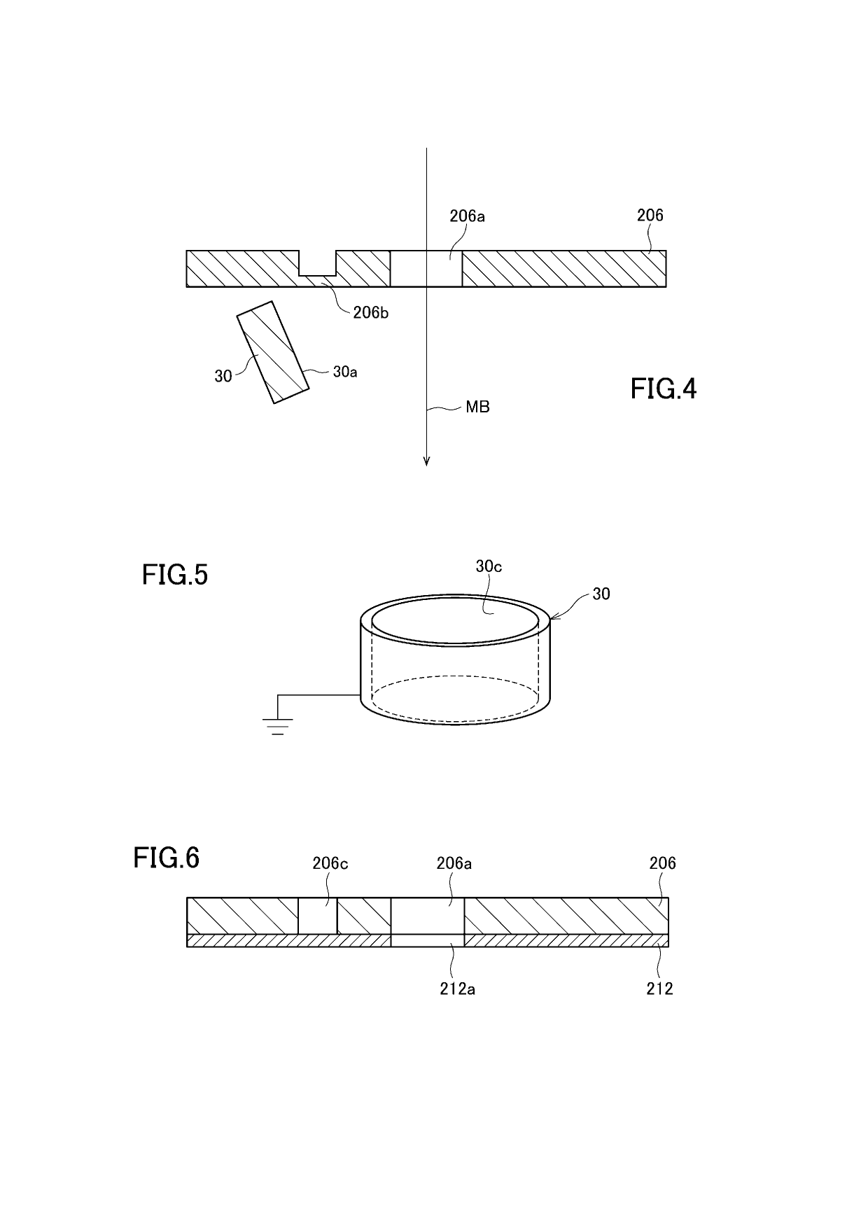

In the above embodiment, the configuration has been described in which the lateral surface 30a of the electron absorbing member 30 that absorbs the beam scattered by the scattering section 206b is parallel to the travel direction of the beam on which no blanking deflection is performed; however, as illustrated in FIG. 4, the electron absorbing member 30 may be disposed so that the lateral surface 30a is inclined with respect to the beam travel direction.

As illustrated in FIG. 5, the electron absorbing member 30 may have a cylindrical shape. The cylindrical electron absorbing member 30 is installed such that the beam on which no blanking deflection is performed passes through the center of the electron absorbing member 30. The beam scattered by the scattering section 206b is absorbed by an inner circumferential surface 30c of the cylinder.

The beam on which blanking deflection has been performed by an individual blanker of the blanking aperture array substrate 204 may also be scattered by the scattering section 206b, and then absorbed by the electron absorbing member 30.

In the above embodiment, the configuration has been described in which the beam is scattered by the scattering section 206b provided in the stopping aperture substrate 206; however, as illustrated in FIG. 6, a through-hole 206c penetrating through the stopping aperture substrate 206 may be formed instead of the scattering section 206b, and a scattering thin film 212 may be formed as a scattering section on the upper surface or the lower surface of the stopping aperture substrate 206. The material of the scattering thin film 212 may be, for example, tantalum, ruthenium, or silicon, and may be the same as or different from the material of the stopping aperture substrate 206. It is preferable that the thickness of the scattering thin film 212 be approximately 1 to 20 μm.

The multi-beam deflected by the collective blanking deflector 207 passes through the through-hole 206c, and is then scattered by the scattering thin film 212.

The scattering thin film 212 may be formed to close the through-hole 206c. When the scattering thin film 212 is formed on the entire lower surface of the stopping aperture substrate 206, an opening 212a is formed in the scattering thin film 212 so as not to close the opening 206a.

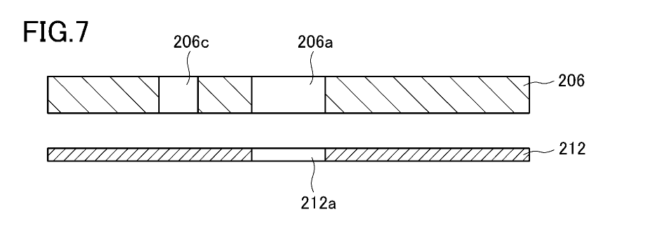

The scattering thin film 212 may be integrally formed with, installed in contact with, or spaced apart from the stopping aperture substrate 206. For example, as illustrated in FIG. 7, the scattering thin film 212 may be disposed away from the lower surface of the stopping aperture substrate 206.

The stopping aperture substrate 206 illustrated in FIG. 3 shows the configuration in which the scattering section 206b is located on the lower surface side (downstream in the beam travel direction); however, the scattering section 206b may be located on the upper surface side, or separated from the upper surface, and the lower surface. Alternatively, the scattering section 206b may be formed inside the through-hole 206c. In addition to a thin film, a scattering section in a lattice pattern, or reticular pattern may be used as the scattering section. These may be made of metal, and grounded. Alternatively, the scattering section may be made of a porous insulating material.

In the above embodiment, the configuration has been described in which a multi-beam is formed by an electron beam emitted from the electron source 201 passing through the shaping aperture array substrate 203; however, the method of forming a multi-beam is not limited to this, and another configuration may be used, for example, a multi-beam is formed by emitting beams from multiple electron sources or photocathodes.

In the above embodiment, a writing apparatus using a multi-beam has been described, but the embodiment may also be applied to a writing apparatus using a single beam.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A charged particle beam writing apparatus comprising:
a charged particle source generating and emitting a beam;
a blanker controlling ON/OFF of the beam;
a stopping aperture substrate having a first opening through which the beam, when controlled to be ON by the blanker, passes toward a substrate;
a scattering section through which the beam transmits while being scattered when deflected by the blanker to be OFF; and
an absorbing member that absorbs the beam having transmitted through the scattering section.

2. The charged particle beam writing apparatus according to claim 1,
wherein a second opening is formed in the stopping aperture substrate, and the scattering section is provided to close the second opening.

3. The charged particle beam writing apparatus according to claim 1,
wherein the scattering section is disposed apart from the stopping aperture substrate.

4. The charged particle beam writing apparatus according to claim 1,
wherein the beam is a multi-beam, and the blanker comprises a plurality of individual blankers that individually perform blanking deflection on the multi-beam.

5. The charged particle beam writing apparatus according to claim 1,
wherein the beam is a multi-beam, andthe blanker is a collective blanking deflector configured to collectively perform blanking deflection on the multi-beam.

6. The charged particle beam writing apparatus according to claim 1,
wherein the scattering section includes at least one of tantalum, ruthenium, and silicon.

7. The charged particle beam writing apparatus according to claim 1,
wherein the absorbing member includes at least one of titanium and aluminum.
